(19) United States
(12) Patent Application Publication
(10) Pub. No.: US 2012/0267663 A1
(43) Pub. Date: Oct. 25, 2012

(54) LIGHT EMITTING DIODE PACKAGE AND MANUFACTURING METHOD THEREOF

(76) Inventors: Hun Yong PARK, Suwon-si (KR); Ji Hyun Kim, Iksan-si (KR); Jae Sung You, Suwon-si (KR); Seong Deok Hwang, Seoul (KR); Young Hee Song, Seongnam-si (KR)

(21) Appl. No.: 13/426,342

(22) Filed: Mar. 21, 2012

(30) Foreign Application Priority Data
Mar. 21, 2011 (KR) 10-2011-0024859

(51) Int. Cl. H01L 33/58

(52) U.S. Cl. 257/98; 438/27; 257/E33.059

(57) ABSTRACT

A light emitting diode (LED) package refracting or reflecting light emitted from an LED chip is disclosed. The LED package may include a substrate, an LED chip mounted on the substrate, a lens unit formed by injecting an encapsulant adapted to enclose and protect the LED chip, and at least one refraction member disposed in the lens unit. The at least one refraction member may refract or reflect the light emitted from the LED chip.

### CROSS-REFERENCE TO RELATED APPLICATION

This application claims the benefit of Korean Patent Application No. 10-2011-0024859, filed on Mar. 21, 2011, in the Korean Intellectual Property Office, the disclosure of which is incorporated herein by reference.

### BACKGROUND

1. Field of the Invention

The present invention relates to a light emitting diode (LED) package for emitting a wide beam of light to the outside by providing a lens unit or a mold unit with a refraction member that refracts or reflects light emitted from an LED chip.

2. Description of the Related Art

A light light emitting diode (LED) chip refers to a semiconductor device capable of implementing various colors of light, by forming a light source through alteration of compound semiconductor materials such as gallium arsenide (GaAs), aluminum GaAs (AlGaAs), gallium nitride (GaN), indium gallium indium phosphide (InGaInP).

Recently, the LED chip has been developed from a general low-brightness version to a high-brightness high-quality version. Accordingly, the LED chip is manufactured in a package form and applied to various fields including interior or exterior lighting, a headlight of a vehicle, interior lighting of a vehicle, a backlight unit, and the like.

A general LED package includes a cavity molded into a shape of a reflection cup and made of a highly-reflective material so as to reduce a loss of light being emitted from an LED chip.

A mold unit of the LED package is configured in the following manner. At least one LED chip is mounted on a lead frame including a molding material, in a part of the cavity. Here, die bonding or wire bonding is performed. Next, silicon-based or epoxy-based polymer, in the form of gel, having excellent optical characteristics and thermal resistance, is put in the cavity, thereby completing the mold unit.

Next, a lens is formed at an upper portion of the mold unit of the LED package. Here, the lens is adapted to emit light emitted from the LED chip.

The LED package may apply a plurality of lens molding methods with respect to a substrate-type LED package in order to increase thermal stability while reducing a loss of light caused by diffusion as the reflection cup is added. Accordingly, light extraction efficiency may be increased.

Generally, the LED package includes an encapsulant to protect the LED chip from the outside while allowing light emission.

The LED chip has a high degree of straightness of light emission. Therefore, the LED chip may be useful as a backlight source for emitting light to a particular emission surface.

Light directivity of the LED package may be enhanced using an aspheric lens with a concave center portion. However, the enhancement is technically limited. Also, although a view angle of the LED package may be increased by diffusion using air bubble, an increase in a refractive index is limited.

### SUMMARY

According to an aspect of the present invention, there is provided a light emitting diode (LED) package including a substrate; an LED chip mounted on the substrate, a lens unit formed by injecting an encapsulant adapted to enclose and protect the LED chip, and at least one refraction member disposed in the lens unit.

The at least one refraction member may refract or reflect light emitted from the LED chip.

The at least one refraction member may include at least one foreign substance having a different refractive index from the lens unit.

The lens unit may be provided in a spherical shape or a bat-wing shape of which a center is concave.

The LED package may further include a high-reflectivity coating layer disposed on an upper surface of the substrate.

A refractive index for refracting or reflecting light emitted from the LED chip may be adjusted by a size or number of the at least one refraction member.

The at least one refraction member may be position-controlled according to viscosity of the encapsulant.

According to another aspect of the present invention, there is provided an LED package including a package body comprising a cavity and a lead frame inserted at one side of a bottom surface of the cavity to be exposed on either side of the cavity, an LED chip mounted on the bottom surface of the cavity and electrically connected with the lead frame, a mold unit formed by injecting a mold resin in the cavity on which the LED chip is mounted, a lens unit formed by injecting a transparent resin on the mold unit, and at least one first refraction member disposed in the lens unit.

The LED package may further include at least one second refraction member disposed in the mold unit.

The at least one first refraction member or the at least one second refraction member may refract or reflect light emitted from the LED chip.

The at least one first refraction member or the at least one second refraction member may include at least one air bubble or at least one foreign substance having a different refractive index from the lens unit.

The lens unit may be provided in a spherical shape or a bat-wing shape of which a center is concave.

According to another aspect of the present invention, there is provided a manufacturing method for an LED package, the method including preparing a substrate, mounting an LED chip on the substrate, forming a lens unit by injecting an encapsulant adapted to enclose and protect the LED chip, and forming at least one refraction member in the lens unit.

The forming of the at least one refraction member may include forming at least one air bubble by injecting gas generated from a micro metering pump into the lens unit using a syringe or a micro glass tube.

The manufacturing method may further include forming at least one refraction member in a mold for forming the lens unit, forming the lens unit by injecting the encapsulant in the mold, and curing the lens unit.

According to another aspect of the present invention, there is provided a manufacturing method for an LED package, the method including preparing a package body that comprises a cavity and a lead frame inserted at one side of a bottom surface of the cavity to be exposed on either side of the cavity, mounting an LED chip on the bottom surface of the cavity, electrically connecting the LED chip with the lead frame, forming a mold unit by injecting a mold resin in the cavity on which the LED chip is mounted, forming a lens unit by injecting a transparent resin on the mold unit, and forming at least one refraction member in the lens unit.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a sectional view illustrating a structure of a light emitting diode (LED) package according to an embodiment of the present invention;

FIG. 2 is a perspective view illustrating a structure of the LED shown in FIG. 1;

FIG. 3 is a sectional view illustrating a structure of an LED according to another embodiment of the present invention;

FIGS. 4 and 5 are sectional views illustrating different structures of a lens unit of an LED package according to an embodiment of the present invention;

FIG. 6A is a radial graph illustrating view angle characteristics after an air bubble is applied according to an embodiment of the present invention and FIG. 6B is a radial graph illustrating the view angle characteristics before the air bubble is applied according to a conventional art;

FIG. 7A is a graph illustrating optical pattern characteristics after an air bubble is applied according to an embodiment of the present invention and FIG. 7B is a graph illustrating the optical pattern characteristics before the air bubble is applied according to a conventional art;

FIGS. 8 and 9 are views illustrating various forms of a refraction member of an LED package according to an embodiment of the present invention;

FIG. 10 is a graph illustrating uniformity influenced by a view angle according to a size of an air bubble, according to an embodiment of the present invention;

FIGS. 11 and 12 are views illustrating a method of manufacturing a refraction member using a syringe or a micro glass tube, according to an embodiment of the present invention; and

FIGS. 13 and 14 are views illustrating a method of manufacturing a refraction member using a mold, according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. However, the aspect of the present invention is not limited to the exemplary embodiments.

In the following description, when it is determined that a detailed description of well-known functions related to the present invention and the construction thereof would make the gist of the present invention obscure, they will be omitted. The terminology used herein is for the purpose of describing particular embodiments only and the definition may be varied according to the intention of a user, an operator, or customs. Therefore, the terms and words should be defined based on a description of this specification.

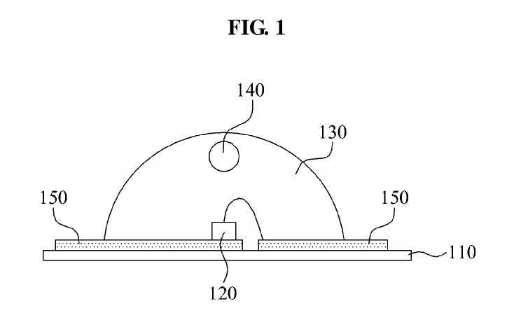

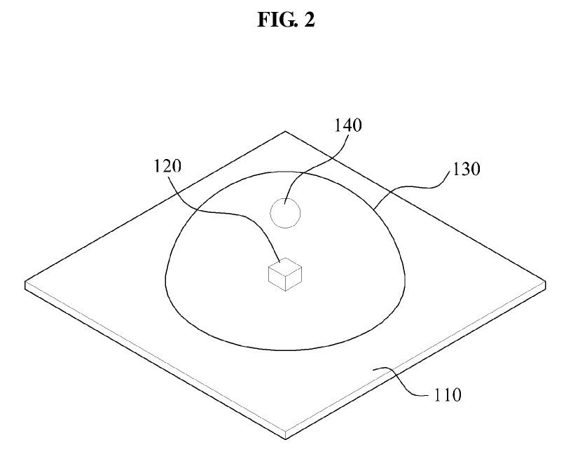

FIG. 1 is a sectional view illustrating a structure of a light emitting diode (LED) package according to an embodiment of the present invention. FIG. 2 is a perspective view illustrating a structure of the LED shown in FIG. 1.

The LED package may include a substrate 110, an LED chip 120 mounted on the substrate 110, a lens unit 130 including an encapsulant adapted to enclose and protect the LED chip 120, and at least one refraction member 140 disposed in the lens unit 130.

The lens unit 130 of the LED package may be formed by molding, for example transfer molding or injection molding, and disposed on the substrate 110 on which the LED chip 120 is mounted. The at least one refraction member 140 is formed in the lens unit 130 to refract or reflect light emitted from the LED chip 120.

The LED package may include, as the at least one refraction member 140, at least one air bubble or at least one foreign substance having a different refractive index from the lens unit 130. By the existence of the at least one refraction member 140, a view angle of the light emitted from the LED chip 120 may be increased.

Hereinafter, the at least one refraction member 140 will be described as the air bubble.

The LED package may include a high-reflectivity coating layer 150 disposed on an upper surface of the substrate 110, to increase extraction efficiency of the light emitted from the LED chip 120.

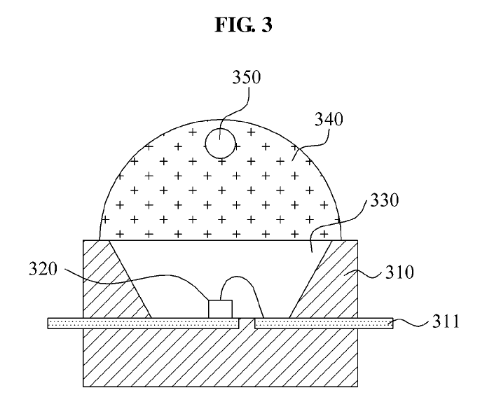

FIG. 3 is a sectional view illustrating a structure of an LED package according to another embodiment of the present invention.

The LED package according to the present embodiment includes a package body 310, an LED chip 320, a mold unit 330, a lens unit 340, and a first refraction member 350.

The package body 310 may include a cavity. The cavity may include a lead frame 311 inserted at one side of a bottom surface and exposed on either side of the cavity.

The LED chip 320 may be mounted on the bottom surface of the cavity and electrically connected with the lead frame 311.

The mold unit 330 may be formed by injecting a molding resin in the cavity on which the LED chip 320 is mounted.

The lens unit 340 may be formed by injecting a transparent resin on the mold unit 330.

The first refraction member 350 may be disposed in the lens unit 340.

At least one second refraction member may be provided in the mold unit 330.

A light diffuser layer may be further provided between the mold unit 330 and the lens unit 340.

At least one first refraction member 350 or the at least one second refraction member may refract or reflect light emitted from the LED chip 320, thereby increasing a view angle. Consequently, light uniformity may be increased.

The at least one first refraction member 350 or the at least one second refraction member may refract or reflect the light by including at least one air bubble or at least one foreign substance having a different refractive index from the lens unit 340, which is formed by an injection method.

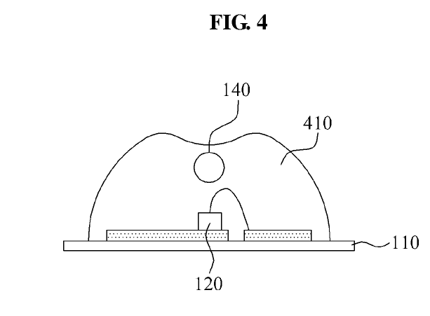

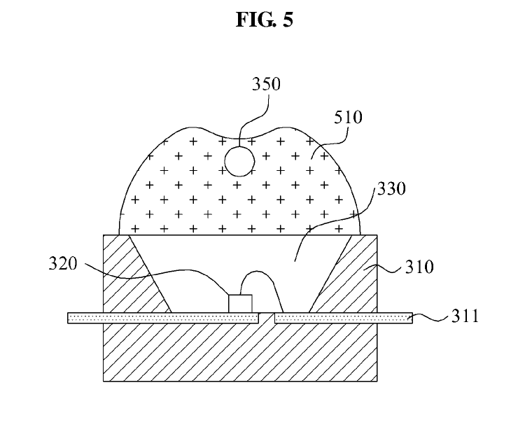

FIGS. 4 and 5 are sectional views illustrating different structures of a lens unit of an LED package according to an embodiment of the present invention.

Referring to FIG. 1, the lens unit 130 of the LED package is formed into a spherical shape but not limited thereto. For example, a lens unit 410 as shown in FIG. 4 is provided in a bat-wing shape of which a center is concave. Therefore, a degree of light refraction may be controlled using the refraction member 140 while at the same time a view angle may be controlled using the lens unit 410.

Referring to FIG. 3, although the lens unit 340 may also be provided in a spherical shape, it is not limited thereto. For example, the lens unit 510 as shown in FIG. 5 may be to provided in a bat-wing shape of which a center is concave. Therefore, a degree of light refraction may be controlled using the first refraction member 350 while at the same time a view angle may be controlled using the lens unit 510.

At least one refraction member 140 of the LED package according to the embodiment of the present invention may be position-controlled according to viscosity of the encapsulant.

In the LED package according to another embodiment of the present invention, the at least one first refraction member 350 may be position-controlled according to viscosity of the transparent resin. The at least one second refraction member may be position-controlled according to viscosity of the molding resin.

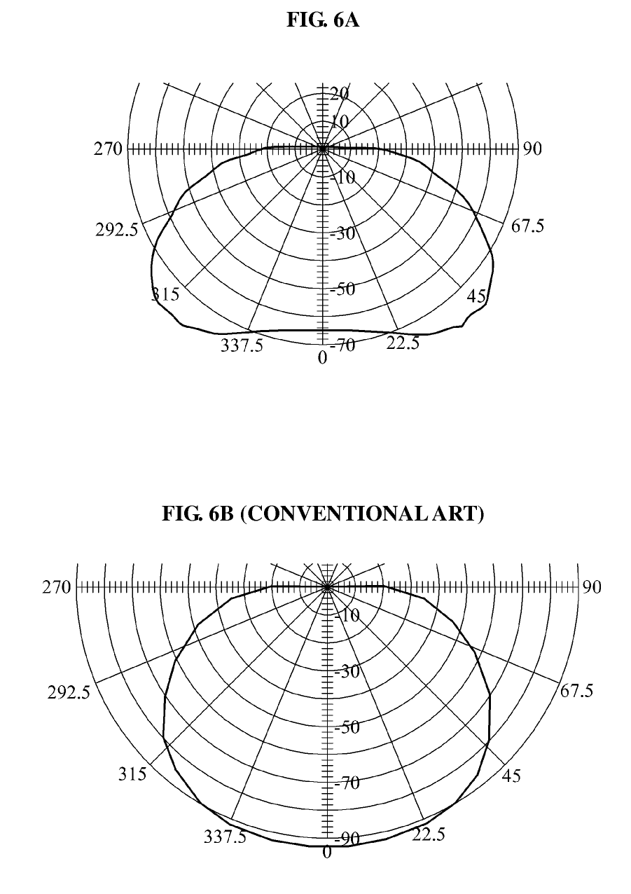

FIG. 6A is a radial graph illustrating view angle characteristics after an air bubble is applied according to an embodiment of the present invention. FIG. 6B is a radial graph illustrating the view angle characteristics before the air bubble is applied according to a conventional art.

The optical characteristics determined by a refraction member may be controlled by adjusting the air bubble to emit light at a desired view angle using a dedicated injection method or by adjusting a position of the refraction member according to viscosity of an encapsulant, a molding resin, or a transparent resin.

For example, a size and position of the air bubble may be adjusted so that the LED package has a view angle as shown in FIG. 6A.

Refractive index for refracting or reflecting the light emitted from the LED chips 120 and 320 may be adjusted according to a size or number of the at least one refraction members 140 and 350.

The desired view angle and light uniformity may be guaranteed according to the size and number of the at least one refraction members 140 and 350, for example the air bubbles.

Since an interface is spontaneously generated between the air bubble and the encapsulant enclosing the LED chip, the interface may be capable of internally reflecting and refracting the light and minimizing loss of the light.

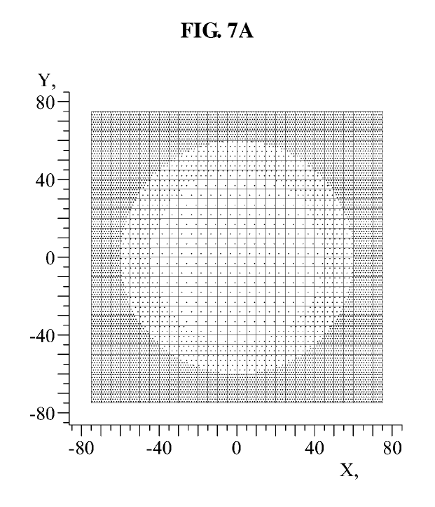

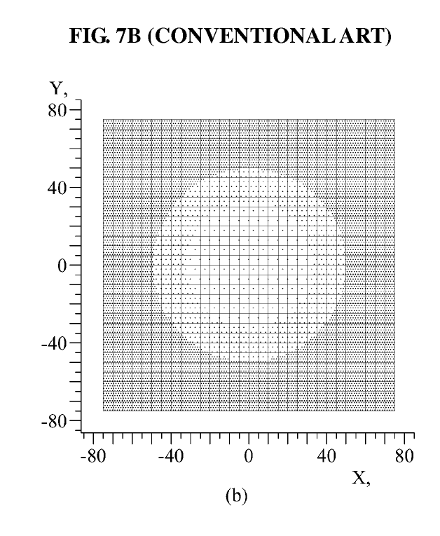

FIG. 7A is a graph illustrating optical pattern characteristics after an air bubble is applied according to an embodiment of the present invention and FIG. 7B is a graph illustrating the optical pattern characteristics before the air bubble is applied according to a conventional art.

Since the LED chip emits light as shown in FIG. 7A, an optical pattern on a predetermined emission surface may secure higher light uniformity in comparison to a case of FIG. 7B.

The LED package may include, as a refraction member, at least one air bubble or a foreign substance having a different refractive index from an optically transparent encapsulant, the refraction member disposed in the encapsulant in various configurations. Accordingly, the view angle and the light uniformity may be increased.

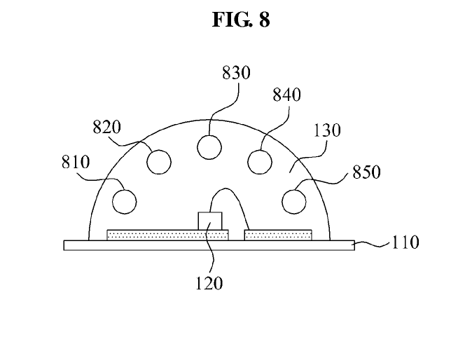

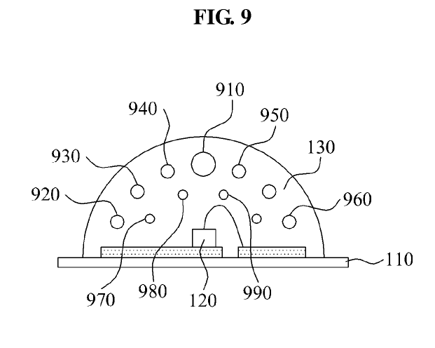

FIGS. 8 and 9 are views illustrating various forms of a refraction member of an LED package according to an embodiment of the present invention.

For example, referring to FIG. 8, the LED package includes air bubbles 810 to 850 disposed in an encapsulant and arranged along an outline of a lens unit, as the refraction member, thereby increasing the view angle.

As another example, referring to FIG. 9, the LED package may include air bubbles 910 to 990 in different sizes, as the refraction member, which are disposed in the encapsulant and arranged in a scattered manner. Accordingly, a desired view angle may be achieved.

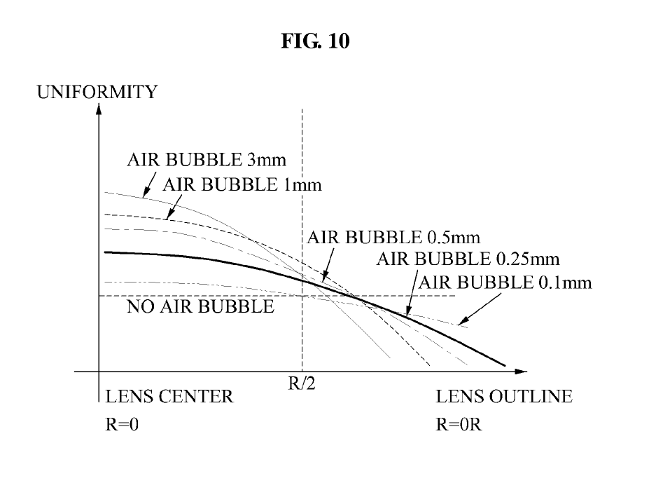

FIG. 10 is a graph illustrating uniformity influenced by a view angle according to a size of an air bubble, according to an embodiment of the present invention.

Referring to FIG. 10, in comparison to a case without the air bubble, light emission uniformity may be increased when the air bubble is about 0.1 mm or more in size and disposed at a position corresponding to about ½ of a radius of a lens unit. However, the size and the position of the air bubble are not specifically limited.

The air bubble may obtain a favorable view angle when disposed near an LED chip with respect to a height direction. However, the direction is not specifically limited to the height direction.

The size of the air bubble may be considered to be a size of a group of small air bubbles.

Hereinafter, a manufacturing method of an LED package, according to an embodiment of the present invention, will be described.

A substrate is prepared. An LED chip is mounted on the substrate. An encapsulant is injected to enclose and protect the LED chip, thereby forming a lens unit. At least one refraction member is formed in the lens unit, thus completing manufacturing of the LED package.

A highly-reflective coating layer may be further applied to an upper surface of the substrate in order to increase extraction efficiency of light emitted from the LED chip.

According to another embodiment, a package body of the LED package is prepared. The package body may include a cavity, and a lead frame inserted at one side of a bottom surface of the cavity to be exposed on either side of the cavity. The LED chip is mounted on the bottom surface of the cavity.

Next, the LED chip is electrically connected with the lead frame. A mold unit is formed by injecting a molding resin in the cavity on which the LED chip is mounted. A lens unit is formed by injecting a transparent resin on the mold unit.

Finally, the LED package may be completed by forming at least one refraction member in the lens unit.

In addition, a light diffuser layer may be provided between the mold unit and the lens unit.

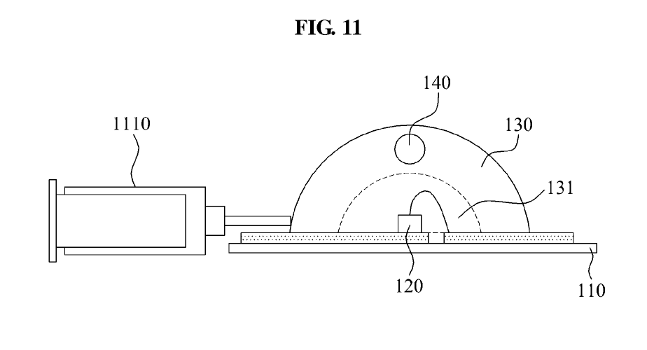

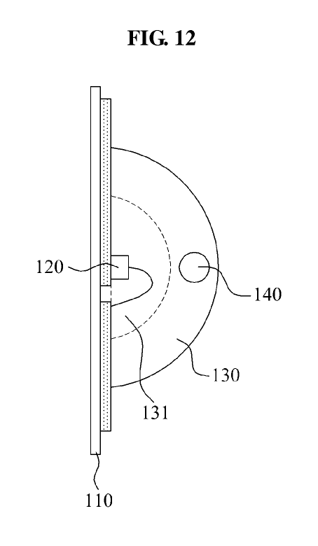

FIGS. 11 and 12 are views illustrating a method of manufacturing a refraction member using a syringe or a micro glass tube, according to the embodiment of FIG. 1.

Referring to FIG. 11, when forming the at least one refraction member in the lens unit 130, gas generated from a micro metering pump is injected into the lens unit 130 using a syringe or a micro glass tube, thereby forming the at least one air bubble. As shown in FIG. 12, the position of the air bubble may be adjusted based on a guide 131 during curing of the completed LED package.

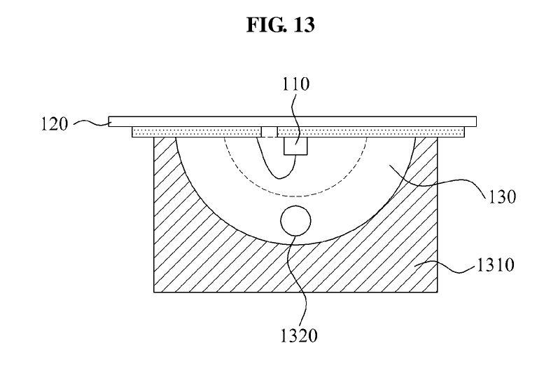

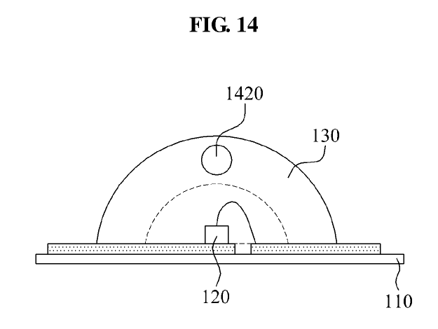

FIGS. 13 and 14 are views illustrating a method of manufacturing a refraction member using a mold, according to an embodiment of the present invention.

Referring to FIG. 13, at least one refraction member 1320 is formed in a mold 1310 for forming the lens unit 130, and an encapsulant is injected in the mold 1310, thereby forming the lens unit 130. Next, as shown in FIG. 14, a position of the air bubble may be adjusted based on a guide 131 during curing of the completed LED package.

The air bubble or the refraction member having a different refractive index from the encapsulant may be formed in the encapsulant, so as to refract or reflect the light emitted from the LED chip. As a result, a view angle may be increased and light uniformity of the LED package may be increased.

As described in the foregoing embodiments, since the air bubble is applied as the refraction member, a thermal shock from the outside of the encapsulant may be reduced.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A light emitting diode (LED) package comprising:
a substrate;
an LED chip mounted on the substrate;
a lens unit formed by injecting an encapsulant adapted to enclose and protect the LED chip; and
at least one refraction member disposed in the lens unit.

2. The LED package of claim 1, wherein the at least one refraction member refracts or reflects light emitted from the LED chip.

3. The LED package of claim 1, wherein the at least one refraction member comprises at least one air bubble or at least one foreign substance having a different refractive index from the lens unit.

4. The LED package of claim 1, wherein the lens unit is provided in a spherical shape or a bat-wing shape of which a center is concave.

5. The LED package of claim 1, further comprising a highly-reflective coating layer disposed on an upper surface of the substrate.

6. The LED package of claim 1, wherein a refractive index for refracting or reflecting light emitted from the LED chip is adjusted by a size or number of the at least one refraction member.

7. The LED package of claim 1, wherein the at least one refraction member is position-controlled according to viscosity of the encapsulant.

8. A light emitting diode (LED) package comprising:
a package body comprising a cavity and a lead frame inserted at one side of a bottom surface of the cavity to be exposed on either side of the cavity;
an LED chip mounted on the bottom surface of the cavity and electrically connected with the lead frame;
a mold unit formed by injecting a mold resin in the cavity on which the LED chip is mounted;
a lens unit formed by injecting a transparent resin on the mold unit; and
at least one first refraction member disposed in the lens unit.

9. The LED package of claim 8, further comprising at least one second refraction member disposed in the mold unit.

10. The LED package of claim 9, wherein the at least one first refraction member or the at least one second refraction member refracts or reflects light emitted from the LED chip.

11. The LED package of claim 9, wherein the at least one first refraction member or the at least one second refraction member comprises at least one air bubble or at least one foreign substance having a different refractive index from the lens unit.

12. The LED package of claim 8, wherein the lens unit is provided in a spherical shape or a bat-wing shape of which a center is concave.

13. The LED package of claim 8, further comprising a light diffuser layer disposed between the mold unit and the lens unit.

14. The LED package of claim 8, wherein a refractive index for refracting or reflecting light emitted from the LED chip is adjusted by a size or number of the at least one first refraction member.

15. The LED package of claim 8, wherein the at least one first refraction member is position-controlled according to viscosity of the transparent resin.

16. The LED package of claim 9, wherein the at least one second refraction member is position-controlled according to viscosity of the mold resin.

17. A manufacturing method for a light emitting diode (LED) package, the method comprising:
preparing a substrate;
mounting an LED chip on the substrate;
forming a lens unit by injecting an encapsulant adapted to enclose and protect the LED chip; and
forming at least one refraction member in the lens unit.

18. The manufacturing method of claim 17, wherein the at least one refraction member refracts or reflects light emitted from the LED chip.

19. The manufacturing method of claim 17, wherein the at least one refraction member comprises at least one air bubble or at least one foreign media having a different refractive index from the lens unit.

20. The manufacturing method of claim 17, further comprising forming a highly-reflective coating layer on an upper surface of the substrate.

21. The manufacturing method of claim 19, wherein the forming of the at least one refraction member comprises:
forming at least one air bubble by injecting gas generated from a micro metering pump into the lens unit using a syringe or a micro glass tube.

22. The manufacturing method of claim 17, further comprising:
forming at least one refraction member in a mold for forming the lens unit;
forming the lens unit by injecting the encapsulant in the mold; and
curing the lens unit.

23. A manufacturing method for a light emitting diode (LED) package, the method comprising:
preparing a package body that comprises a cavity and a lead frame inserted at one side of a bottom surface of the cavity to be exposed on either side of the cavity;
mounting an LED chip on the bottom surface of the cavity;
electrically connecting the LED chip with the lead frame;
forming a mold unit by injecting a mold resin in the cavity on which the LED chip is mounted;
forming a lens unit by injecting a transparent resin on the mold unit; and
forming at least one refraction member in the lens unit.

24. The manufacturing method of claim 23, further comprising forming a light diffuser layer between the mold unit and the lens unit.
